(19) United States
(12) Patent Application Publication
(10) Pub. No.: US 2014/0076773 A1
(43) Pub. Date: Mar. 20, 2014

(54) FRONT OPENING UNIFIED POD HAVING INLET AND OUTLET

(71) Applicant: GUDENG PRECISION INDUSTRIAL CO., LTD., NEW TAIPEI CITY (TW)

(72) Inventors: CHI-TE HUANG, TAOYUAN COUNTY (TW); SHAO-WEI LU, TAOYUAN COUNTY (TW); YU-LIANG CHOU, TAOYUAN COUNTY (TW)

(73) Assignee: GUDENG PRECISION INDUSTRIAL CO., LTD., NEW TAIPEI CITY (TW)

(21) Appl. No.: 13/719,428

(22) Filed: Dec. 19, 2012

(30) Foreign Application Priority Data
Sep. 17, 2012 (TW) 101134067

(51) Int. Cl. H01L 21/677

(52) U.S. Cl. CPC H01L 21/677
USPC 206/710

(57) ABSTRACT

The present invention relates to a front opening unified pod (FOUP) having three inlets and one outlet. Thereby, the mixing region for the moisture, oxygen, and the filled gas can be increased and the removing efficiency of the moisture and oxygen in the FOUP is enhanced, improving the purging efficiency of the FOUP and shortening the time required for filling gas. In addition, the humidity in the FOUP can be reduced effectively so that the internal environment of the FOUP can reach rapidly the condition suitable for semiconductor fabrication. Hence, the subsequent semiconductor processes can be performed and the preparation time for the processes can be shortened.

### FIELD OF THE INVENTION

The present invention relates generally to a front opening unified pod, and particularly to a front opening unified pod having inlet and outlet.

### BACKGROUND OF THE INVENTION

The conventional wafer carrier named Standard mechanical interface (SMIF) is used for storing and transferring 8-inch wafers. Nonetheless, with the advancement in semiconductor manufacturing technologies, the size of wafer has increased to 12 or even 18 inches. For fitting larger wafers, the wafer carrier for such large sized wafers is different from the one for 8-inch wafers and is called front opening unified pod (FOUP). In the FOUP, wafers are maintained in an airtight space for avoiding contact of dust, moisture, oxygen, and molecular pollutants with the wafer surfaces.

The FOUP according to the prior art has two inlets and two outlets. When gas enters the FOUP from the two inlets, most gas is mixed with the surrounding moisture and oxygen of the two inlets and then diffuses and flows toward the outlets. In order to purge the moisture and oxygen surrounding the region away from the inlets, more gas has to be filled continuously. The more the gas is filled, the more moisture and oxygen can be mixed and replaced, which means better purging efficiency. On the contrary, the fewer the gas is filled, the fewer moisture and oxygen can be mixed, leading to lower purging efficiency.

The filled gas surrounding the region of the two inlets is more. Thereby, more moisture and oxygen surrounding this region can be mixed and replaced. On the contrary, the filled gas surrounding the region away from the two inlets is more. Thereby, fewer moisture and oxygen surrounding this region can be mixed and replaced and thus leading to lower purging efficiency around this region. For solving this problem, more gas has to be filled continuously to the FOUP until the humidity therein reduces to the environment suitable for semiconductor fabrication. This will consume much time and energy. In addition, the removing efficiency for the moisture and oxygen in an FOUP is inferior; the humidity in the FOUP cannot be lowered rapidly.

Accordingly, the present invention provides an FOUP having three inlets and one inlet. Thereby, the removing efficiency for the moisture and oxygen in an FOUP is enhanced. Hence, the humidity in the FOUP can be lowered rapidly.

### SUMMARY

An objective of the present invention is to provide an FOUP having inlet and outlet. The FOUP has three inlets and one outlet. Two inlets are located at the rear end of the FOUP; one inlet and the outlet are located at the front end thereof. Thereby, the mixing region for the filled gas with the moisture and oxygen in the FOUP is increased and thus enhancing the removing efficiency of the moisture and oxygen in the FOUP. Accordingly, the purging efficiency of the FOUP is improved.

Another objective of the present invention is to provide an FOUP having inlet and outlet. The FOUP has three inlets and one outlet. Thereby, the removing efficiency of the moisture and oxygen in the FOUP is enhanced. The humidity in the FOUP can be reduced effectively so that the internal environment of the FOUP can reach rapidly the condition suitable for semiconductor fabrication. Hence, the subsequent semiconductor processes can be performed and the preparation time for the processes can be shortened.

Still another objective of the present invention is to provide an FOUP having inlet and outlet. The FOUP has three inlets and one outlet. Thereby, the removing efficiency of the moisture and oxygen in the FOUP is enhanced. In addition, the time for filling gas in the FOUP is shortened.

The present invention provides an FOUP having inlet and outlet, which comprises a door and a case having an opening. The door is disposed at the case and seals the opening. The bottom of the case comprises a first side, a second side, two first inlets, a second inlet, and an outlet. The first side is not adjacent to the opening. The second side is adjacent to the opening. The two first inlets are disposed on the first side; the second inlet is disposed on the second side and corresponds to the two first inlets, respectively; and the outlet is disposed on the second side and corresponds to the two first inlets and the second inlet, respectively.

### BRIEF DESCRIPTION OF THE DRAWINGS

FIG. 1 shows a schematic diagram of the FOUP according an embodiment of the present invention;

FIG. 2 shows a schematic diagram of the bottom of the FOUP according an embodiment of the present invention;

FIG. 2A shows a schematic diagram of the inlet of the FOUP according an embodiment of the present invention;

FIG. 2B shows another schematic diagram of the inlet of the FOUP according an embodiment of the present invention;

FIG. 3 shows a usage diagram of the FOUP according an embodiment of the present invention; and

FIG. 4A and FIG. 4B show curves of humidity versus time according an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The FOUP according to the prior art has two inlets and two outlets. When gas enters the FOUP from the two inlets, most gas is mixed with the surrounding moisture and oxygen of the two inlets and then diffuses and flows toward the outlets. In order to purge the moisture and oxygen surrounding the region away from the inlets, more gas has to be filled continuously. The more the gas is filled, the more moisture and oxygen can be mixed and replaced, which means better purging efficiency. On the contrary, the fewer the gas is filled, the fewer moisture and oxygen can be mixed, leading to lower purging efficiency.

The filled gas surrounding the region of the two inlets is more. Thereby, more moisture and oxygen surrounding this region can be mixed and replaced. On the contrary, the filled gas surrounding the region away from the two inlets is more. Thereby, fewer moisture and oxygen surrounding this region can be mixed and replaced and thus leading to lower purging efficiency around this region. For solving this problem, more gas has to be filled continuously to the FOUP until the environmental condition, such as humidity, therein reduces to the environment suitable for semiconductor fabrication. This method cannot remove the moisture and oxygen in the FOUP. Besides, the time required for filling gas in the FOUP is increased.

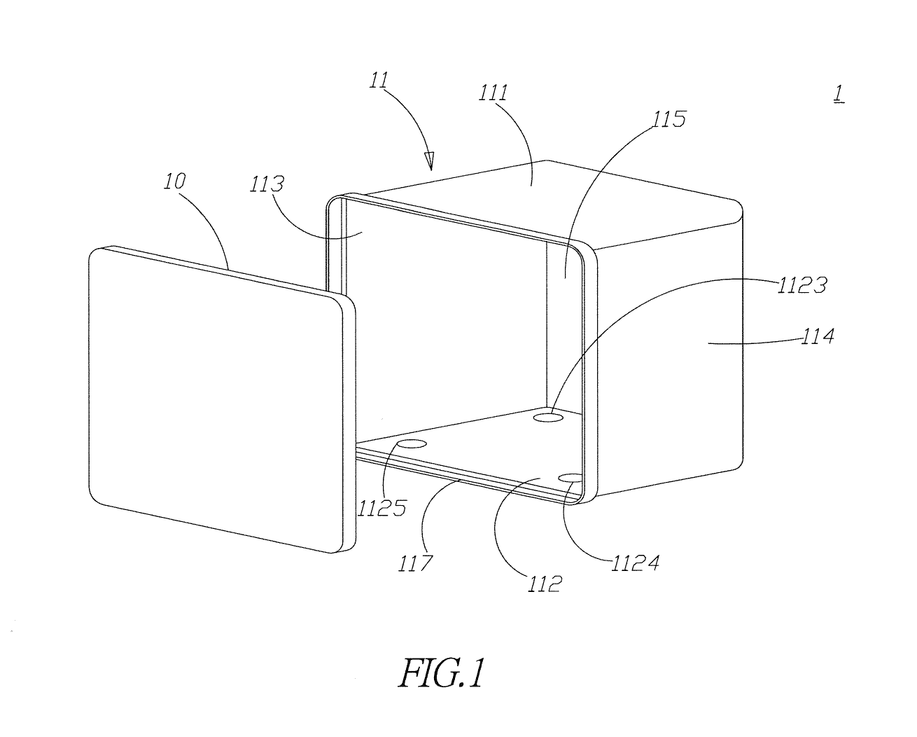

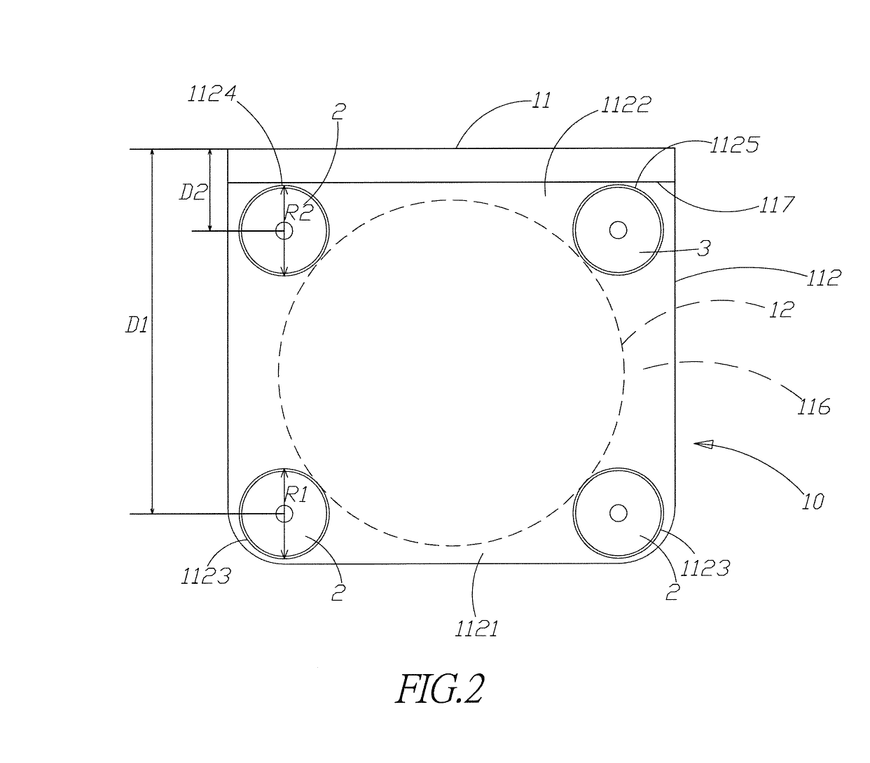

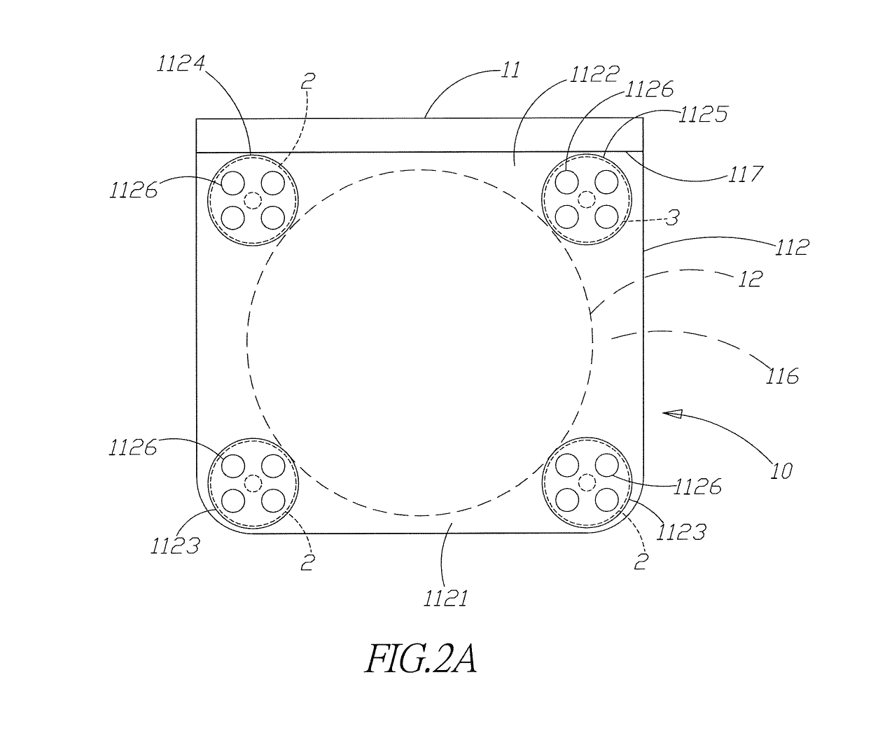

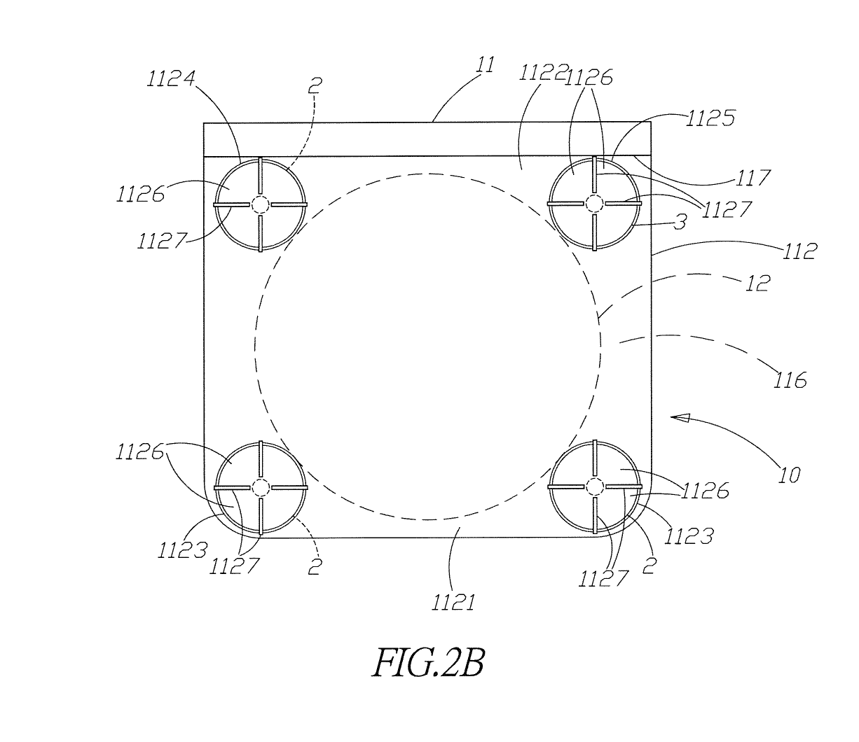

FIG. 1 and FIG. 2 show a schematic diagram of the FOUP and a schematic diagram of the bottom of the FOUP according an embodiment of the present invention. As shown in the figure, the present embodiment provides an FOUP 1 having inlet and outlet. The FOUP 1 comprises a door 10 and a case 11. The case 11 has a top part 111, a bottom part 112, a left sidewall 113, a right sidewall 114, and a rear sidewall 115. The left sidewall 113 and the right sidewall 114 are disposed between the top part 111 and the bottom part 112 and correspond to each other. The four edges of the rear sidewall 115 are connected to the edges of the top part 111, the bottom part 112, the left sidewall 113, and the right sidewall 114, respectively, and thus forming a accommodating space 116 in the case 11 used for accommodating a plurality of wafers 12. The other edges of the top part 111, the bottom part 112, the left sidewall 113, and the right sidewall 114 not connected with the four edges of the rear sidewall 115 form an entry 117. The plurality of wafers 12 are placed into the accommodating space 116 via the entry 117. Finally, the door 10 is disposed at the case 11 and seals the entry 117 for storing and transferring the plurality of wafers 12. Moreover, the FOUP 1 is filled with non-oxygen gas. Thus, the FOUP 1 can maintain high cleanness for preventing pollution on the plurality of wafers 12 from the external environment.

The bottom 112 of the FOUP 1 according to the present embodiment has a first side 1121 and a second side 1122. The first side 1121 is not adjacent to the entry 117 of the case 11. Namely, the first side 1121 is located near the rear end of the FOUP 1. The second side 1122 is adjacent to the entry 117 of the case 11 and corresponds to the first side 1121. Namely, the second side 1122 is near the front end of the FOUP 1. The bottom 112 of the FOUP 1 further includes two first inlets 1123, a second inlet 1124, and an outlet 1125. The two first inlets 1123 are disposed on the first side 1121 of the bottom 112 of the case 11. The second inlet 1124 is disposed on the second side 1122 of the bottom 112 of the case 11 and corresponds to the two first inlets 1123, respectively. The outlet 1125 is disposed on the second side 1122 of the bottom 112 of the case 11 and corresponds to the two first inlets 1123 and the second inlet 1124, respectively. The two first inlets 1123 and the second inlet 1124 have inlet devices 2, such as inlet valves; the outlet 1125 has an outlet device 3, such an outlet valve. The first inlets 1123, the second inlet 1124, or the outlet 1125 can include a plurality of sub-inlets 1126 or sub-outlets, as shown in FIG. 2A. For forming the plurality of sub-inlets 1126 or sub-outlets, at least a rib 1127 can be disposed at the first inlets 1123, the second inlet 1124, or the outlet 1125 for dividing them into a plurality of sub-inlets 1126 or sub-outlets, as shown in FIG. 2B. The rib 1127 can support the inlet device 2 or the outlet device 3.

In order to reduce the moisture and oxygen in the FOUP 1 with the plurality of wafers 12 loaded, the FOUP 1 is first disposed on gas-filling equipment (not shown in the figure). The gas-filling equipment is connected to the two first inlets 1123 and the second inlet 1124 of the FOUP 1 and fills gas into the FOUP 1 via the two first inlets 1123 and the second inlet 1124.

Presently, the maximum size of the FOUP 1 is 12 inches. In the future, the size of the FOUP 1 will be extended to 18 inches. It takes about 3 to 15 minutes to fill a 12-inch FOUP 1 completely via the inlet and outlet disposal according to the prior art. It will take triple the time required for filling a 12-inch FOUP 1 to fill a 18-inch FOUP 1 via the inlet and outlet disposal according to the prior art, leading to increases in costs and time. If the FOUP 1 adopts the inlet and outlet disposal according to the present embodiment, regardless of the size of the FOUP 1, the time required for filling gas to the FOUP 1 could all be shortened.

Refer again to FIG. 2. the ratio of the distance D1 between each first inlet 1123 and the door 10 to the diameter R1 of the first inlet 1123 according to the present embodiment is between 8 and 30; the ratio of the distance D2 between the second inlet 1124 and the door 10 to the diameter R2 of the second inlet 1124 is between 1 and 5. When the size of the FOUP 1 is 18 inches, the size of its inlets is identical to that for 12-inch FOUP 1. Thereby, for shortening the time required for filling the FOUP 1, the flow rate of gas should be increased. Nonetheless, the inlets may be located below or beside the plurality of wafers 12. As the gas with greater flow rate is filled into the FOUP 1 via the inlets, turbulence occurs very possibly. The turbulence can cause the plurality of wafers 12 stored in the FOUP 1 to vibrate, move, rotate, and collide and thus producing polluting particles. At last, the yield of semiconductor devices is lowered. Even worse, the plurality of wafers 12 may crack.

As the line width of semiconductor devices shrinks, the filtering requirement for particles becomes more demanding. For filtering smaller particles, gas-pressure loss occurs in the gas entering pipes. Thereby, the minimum diameter of the inlets is 15 mm. Accordingly, the minimum diameter of the first inlets 1123 and the second inlet 1124 according to the present embodiment is 15 mm. When the size of the FOUP 1 is 18 inches, the diameters of the two first inlets 1123 and the second inlet 1124 can be expanded for filling gas with smaller flow rate without affecting the time required for filling the FOUP 1. Hence, the problem described above can be solved.

Furthermore, according to the present embodiment, as the gas just enters the FOUP 1, the mixing region of the gas with the moisture and oxygen in the FOUP 1 is increased, and thus improving the removing rate for the moisture and oxygen in the FOUP 1. If the FOUP 1 adopts the inlet and outlet disposal according to the prior art, as the gas just enters the FOUP 1, the gas first concentrates in the region surrounding the two inlets. The gas is first mixed with the moisture and oxygen in the region surrounding the two inlets. Then the gas moves toward the two outlets of the FOUP 1, namely, away from the two inlets. However, most gas has already mixed with the moisture and oxygen in the region surrounding the two inlets, leaving no excess gas for mixing with the moisture and oxygen in the region surrounding the two outlets. Thereby, the gas should be filled continuously to the FOUP 1. There will be no excess gas for mixing with the moisture and oxygen in the region surrounding the two outlets and purging until the gas is first mixed completely with the moisture and oxygen in the region surrounding the two inlets and purging in this region is finished.

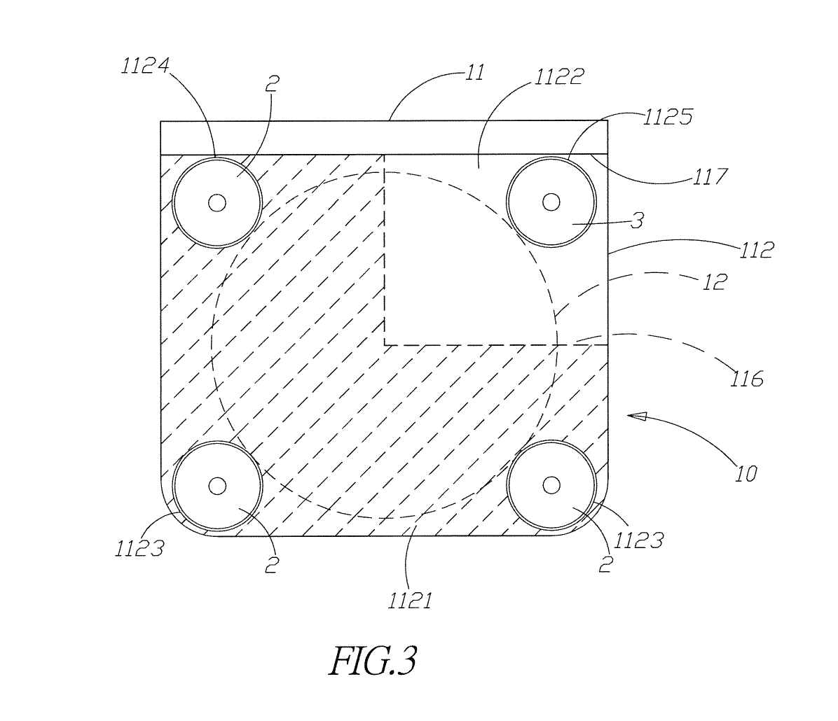

FIG. 3 shows a usage diagram of the FOUP according an embodiment of the present invention. As shown in the figure, according to the present embodiment, two first inlets 1123 are disposed at the rear end of the FOUP 1, namely, the first side 1121 of the case 11; the second inlet 1124 is disposed at the front end of the FOUP 1, namely, the second side 1122 of the case 11. Thereby, the gas enters the FOUP 1 via the two first inlets 1123 and the second inlet 1124. In the beginning, the gas is filled at the rear end and the right front end of the FOUP 1, which means that the gas is first mixed with the moisture and oxygen at the rear end and the right front end of the FOUP 1. Accordingly, the mixing region of the gas with the moisture and oxygen in the FOUP 1, namely, the shaded area in the figure, is increased in the beginning. As the mixing region is increased, it means that the gas-purging region is increased and the unpurging region is smaller. The time required for mixing completely the gas with the moisture and oxygen in the FOUP 1 is thus decreased. According to the present embodiment, the efficiency for filling gas to the FOUP 1 is higher. By the increased region for mixing gas with the moisture and oxygen in the FOUP 1 in the beginning, the mixing efficiency is improved, the removing efficiency for the moisture and oxygen in the FOUP 1 is enhanced, and the purging efficiency is thereby increased.

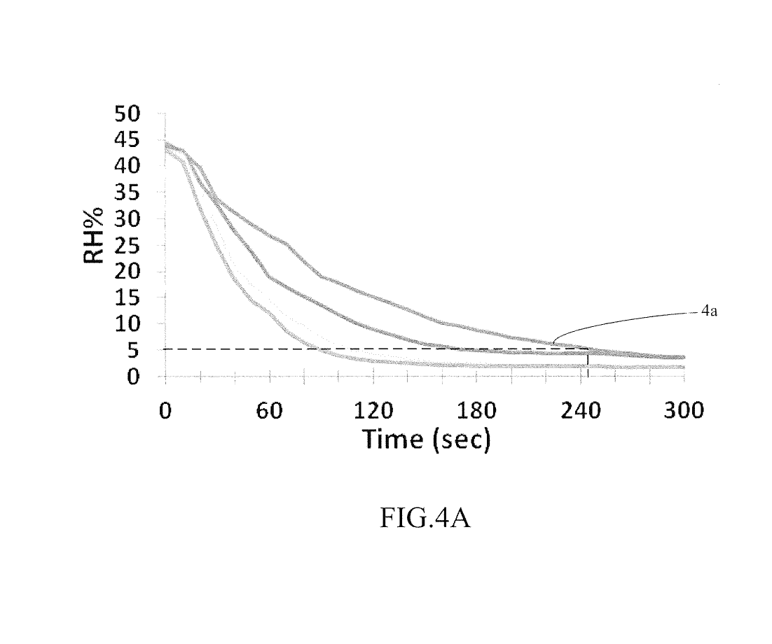

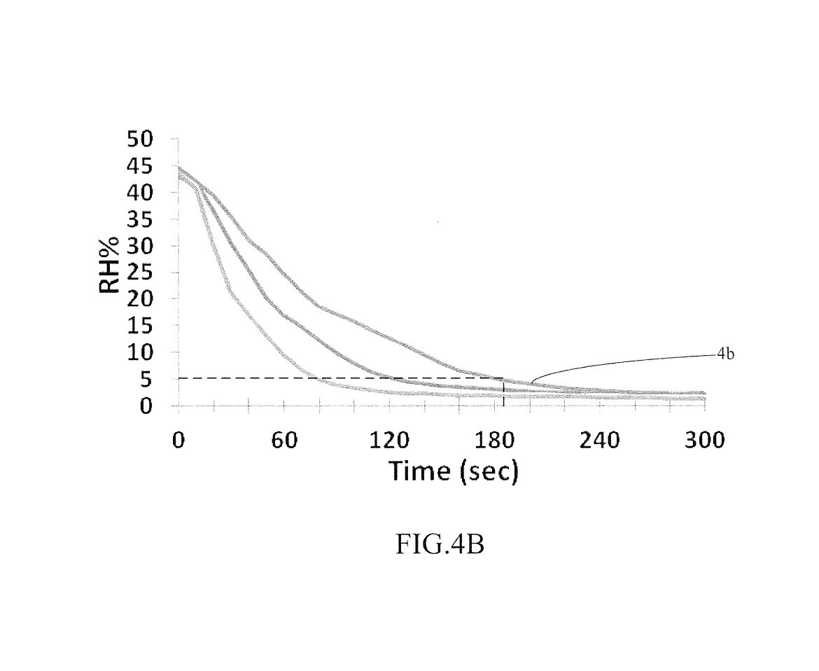

FIG. 4A and FIG. 4B show curves of humidity versus time according an embodiment of the present invention. As shown in the figures, FIG. 4A shows the curves of humidity versus time using the inlet and outlet disposal according to the prior art; FIG. 4B shows the curves of humidity versus time using the inlet and outlet disposal according to the present embodiment.

FIG. 4A includes a first curve 4a; FIG. 4B includes a second curve 4b. When the FOUP adopts the inlet and outlet disposal according to the prior art for filling gas and the gas flow rate is 30 LPM, the curve of humidity versus time in the FOUP is the first curve 4a; when the FOUP adopts the inlet and outlet disposal according to the present embodiment for filling gas and the gas flow rate is 30 LPM, the curve of humidity versus time in the FOUP is the second curve 4b. The diameter of the inlets and the outlets according to the prior art is identical to that of those according to the present embodiment. According to the first and second curves 4a, 4b, it is known that the time required for reducing the humidity of the FOUP using the inlet and outlet disposal according to the prior art to below 5% is 245 seconds, while that time according to the present embodiment is 180 seconds. Obviously, the rate at which the humidity in the FOUP reduces is faster by using the inlet and outlet disposal according to the present embodiment. Thereby, the efficiency for purging the FOUP is higher.

To sum up, the present invention provides an FOUP having three inlets and one outlet. Thereby, when filling gas to the FOUP, the humidity in the FOUP can be reduced effectively, the purging efficiency of the FOUP is improved, and the time required for filling gas is shortened. Hence, the internal environment of the FOUP can reach rapidly the condition suitable for semiconductor fabrication and the preparation time for the processes can be shortened. According to the present invention, proper diameter for the inlets can be deployed according to the size of the FOUP in order to maintain filling gas to the FOUP at a small flow rate. If not so, the turbulence can cause the plurality of wafers stored in the FOUP to vibrate, move, rotate, and collide and thus producing polluting particles. At last, the yield of semiconductor devices is lowered. Even worse, the plurality of wafers 12 may crack.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A front opening unified pod having inlet and outlet, comprising:
a door; and
a case, having an opening, said door disposed at said case and sealing said opening, the bottom of said case comprising:
a first side, not adjacent to said opening;
a second side, adjacent to said opening, and corresponding to said first side;
two first inlets, disposed on said first side;
a second inlet, disposed on said second side, and corresponding to said two first inlets, respectively; and
an outlet, disposed on said second side, and corresponding to said two first inlets and said second inlet, respectively.

2. The front opening unified pod having inlet and outlet of claim 1, wherein the minimum diameter of said first inlets are 15 millimeters.

3. The front opening unified pod having inlet and outlet of claim 1, wherein the minimum diameter of said second inlet is 15 millimeters.

4. The front opening unified pod having inlet and outlet of claim 1, wherein the ratio of the distance between the center of said first inlet and said door to the diameter of said first inlet is between 8 and 30.

5. The front opening unified pod having inlet and outlet of claim 1, wherein the ratio of the distance between the center of said second inlet and said door to the diameter of said second inlet is between 1 and 5.

6. The front opening unified pod having inlet and outlet of claim 1, and further comprising a plurality of inlet devices disposed at said two first inlets and said second inlet, respectively.

7. The front opening unified pod having inlet and outlet of claim 1, and further comprising an outlet device disposed at said outlet.

8. The front opening unified pod having inlet and outlet of claim 1, wherein said two first inlets and said second inlet include a plurality of sub-inlets, respectively, and said outlet further includes a plurality of sub-outlets.

9. The front opening unified pod having inlet and outlet of claim 8, wherein said two first inlets or said second inlet further include at least a rib for dividing said two first inlets or said second inlet into said plurality of sub-inlets.

10. The front opening unified pod having inlet and outlet of claim 8, wherein said outlet further includes at least a rib for dividing said outlet into said plurality of sub-outlets.
